(19) United States
(12) Patent Application Publication
(10) Pub. No.: US 2007/0002914 A1
(43) Pub. Date: Jan. 4, 2007

(54) Semiconductor laser diode having an asymmetric optical waveguide layer

(75) Inventors: Han-youl Ryu, Suwon-si (KR); Kyoung-ho Ha, Seoul (KR); Sung-nam Lee, Suwon-si (KR)

Correspondence Address: BUCHANAN, INGERSOLL & ROONEY PC, POST OFFICE BOX 1404, ALEXANDRIA, VA, 22313-1404, US

(73) Assignee: SAMSUNG ELECTRONICS CO., LTD., Suwon-si (KR)

(21) Appl. No.: 11/475,209

(22) Filed: Jun. 27, 2006

(30) Foreign Application Priority Data
Jun. 27, 2005 (KR) 10-2005-0055902

(51) Int. Cl. H01S 5/00

(52) U.S. Cl. 372/45.01; 372/46.01

(57) ABSTRACT

An n-lower cladding layer, an n-optical waveguide layer, an active layer, a p-optical waveguide layer, and a p-upper cladding layer sequentially form on a substrate, wherein the thickness of the n-optical waveguide layer is greater than the thickness of the p-optical waveguide layer, form a semiconductor laser diode.

### CROSS-REFERENCE TO RELATED PATENT APPLICATION

Priority is claimed to Korean Patent Application No. 10-2005-0055902, filed on Jun. 27, 2005, in the Korean Intellectual Property Office, the disclosure of which is incorporated herein in its entirety by reference.

### BACKGROUND OF THE DISCLOSURE

1. Field of the Disclosure

The present disclosure relates to a semiconductor laser diode, and more particularly, to a semiconductor laser diode with Mg in a p-region that can have low optical loss, and/or in which the thickness of an n-optical waveguide layer can be greater than the thickness of a p-optical waveguide layer, whereby the optical loss can be reduced in various embodiments.

2. Description of the Related Art

Semiconductor laser diodes, used as optical sources for various apparatuses for processing information, need high output optical extraction efficiency relative to applied current to increase information density. Hence, research for optimizing a laser diode structure has been performed.

Power saturation of a device and catastrophic optical damage (COD) limit the operation of the laser diode. Power saturation is caused by the deformation of gain distribution at a high current injection density. COD is damage to a facet of the laser diode caused by a local temperature rise generated in the facet. To overcome these problems, a conventional semiconductor laser diode having a non-absorbing mirror (NAM), a thin active layer (TAL) or an optical cavity has been developed. Such structures decreases optical power density in the facet by broadening an optical mode.

FIG. 1A is a cross-sectional view of a GaInNAs laser diode disclosed in U.S. Pat. No. 5,904,549. The GaInNAS laser diode is a long wavelength laser device.

Referring to FIG. 1A, the conventional GaInNAs laser diode includes a GaAs substrate 6, an n-AlₓGa₁₋ₓAs lower cladding layer 5, a Ga₁₋ₓInₓN_{y}As_{1-y} active layer 4 and a p-AlₓGa₁₋ₓAs upper cladding layer 3, which are sequentially stacked upon one another. A contact layer 2 and a p-electrode layer 1 are formed on the p-AlₓGa₁₋ₓAs upper cladding layer 3. An n-electrode layer 7 is formed on a lower surface of the GaAs substrate 6.

The conventional laser diode has a symmetric optical waveguide structure with the p-AlₓGa₁₋ₓAs upper cladding layer 3 and the n-AlₓGa₁₋ₓAs lower cladding layer 5 having a relatively low refractive index n2 formed symmetrically above and below the Ga₁₋ₓInₓN_{y}As_{1-y} active layer 4 having a relatively high refractive index n1. Therefore, a field is distributed uniformly and is less dense mostly around the p-AlₓGa₁₋ₓAs upper cladding layer 3 and the n-AlₓGa₁₋ₓAs lower cladding layer 5. When such a symmetric optical waveguide structure is applied to the long wavelength GaInNAs quantum well including the GaAs substrate 6, the field is concentrated on a p-cladding layer, and thus serious free carrier absorption occurs when the device operates.

Especially in a semiconductor laser diode having the above symmetrical structure, a material doped with p-type impurities, such as Mg, can cause a lattice defect in the p-AlₓGa₁₋ₓAs upper cladding layer 3. Because of the lattice defect, an optical mode is disposed near the p-AlₓGa₁₋ₓAs upper cladding layer 3, which results in a weakness to optical deterioration.

To overcome this disadvantage, there have been efforts to prevent optical loss inside the device by forming an undoped layer between the active layer and an Mg doped layer such as p-cladding layers as shown in FIG. 1B to reduce overlap of the optical mode and the Mg doped layer.

### SUMMARY OF THE DISCLOSURE

The present disclosure provides a large output semiconductor laser diode which can prevent optical loss due to p-type impurities and enhance optical extraction efficiency.

According to an aspect of the present disclosure, there is provided a semiconductor laser diode having an asymmetric optical waveguide layer, including an n-lower cladding layer, an n-optical waveguide layer, an active layer, a p-optical waveguide layer and a p-upper cladding layer which are sequentially formed on a substrate, wherein the thickness of the n-optical waveguide layer is greater than the thickness of the p-optical waveguide layer.

The thickness of the n-optical waveguide layer may be in a range of 50 to 1000 nm.

The p-optical waveguide layer may be formed of a single- or multi-layered structure and may include InₓGa₁₋ₓN (0≦x≦0.2).

A p-electrode may be formed on the p-upper cladding layer, wherein the p-upper cladding layer may have a mesa structure with a central portion that protrudes.

An electron blocking layer may be formed in the p-optical waveguide layer.

The active layer may have a multiple quantum well (MQW) structure.

### BRIEF DESCRIPTION OF THE DRAWINGS

The above and other features and advantages of the present invention will become more apparent by describing in detail exemplary embodiments thereof with reference to the attached drawings in which:

FIG. 1A is a cross-sectional view of a GaInNAs laser diode disclosed in U.S. Pat. No. 5,904,549;

FIG. 1B is a cross-sectional view of a conventional semiconductor laser diode in which optical absorption caused by Mg is reduced;

FIG. 2A illustrates a structure of semiconductor laser diode having an asymmetric optical waveguide layer according to an embodiment of the present disclosure.

FIG. 2B illustrates the refractive index of each layer and an optical field during laser oscillation of the semiconductor laser diode having an asymmetric optical waveguide layer shown in FIG. 2A.

FIG. 3 is a graph of the confinement factor of a Mg doped layer versus the thickness of an n-optical waveguide layer.

FIG. 4A is a graph of optical output intensity against current applied to a laser diode when the thicknesses of a p-optical waveguide layer and an n-optical waveguide layer are both about 30 nm.

FIG. 4B is a graph of optical output intensity against current applied to a laser diode when the thicknesses of a p-optical waveguide layer and an n-optical waveguide layer are about 30 nm and 300 nm, respectively.

FIG. 5A is a graph of kink energy (power) against the thickness of an n-optical waveguide layer when the thickness of a p-optical waveguide is fixed at about 30 nm.

FIG. 5B is a graph of a vertical angle of a far field pattern with respect to the thickness of an n-optical waveguide layer when the thickness of a p-optical waveguide is fixed at about 30 nm.

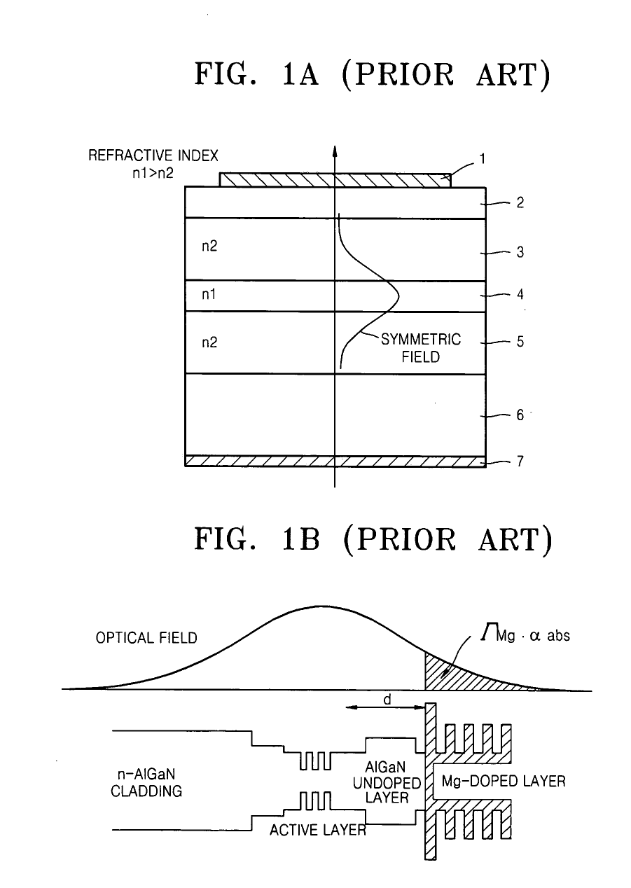

### DETAILED DESCRIPTION OF EXEMPLARY EMBODIMENTS

Hereinafter, the present invention will be described more fully with reference to the accompanying drawings, in which exemplary embodiments of the invention are shown.

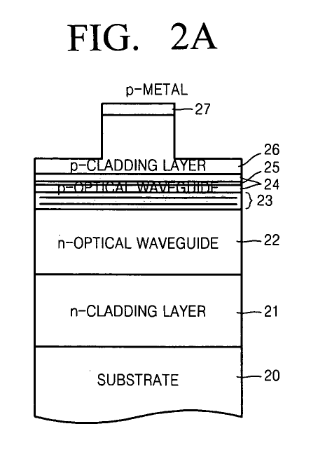

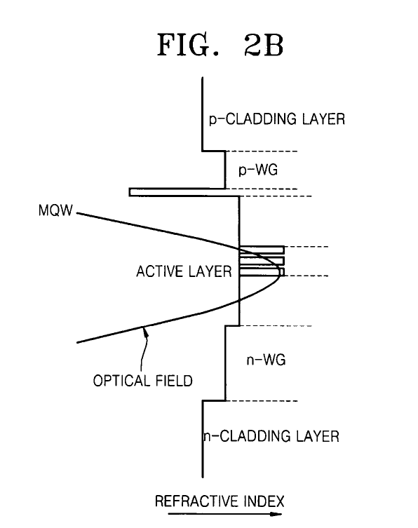

FIG. 2A is a cross-sectional view of a semiconductor laser diode having an asymmetric optical waveguide layer according to an embodiment of the present disclosure.

Referring to FIG. 2A, an n-lower cladding layer 21, an n-optical waveguide layer 22, an active layer 23, a p-optical waveguide layer 24, and a p-upper cladding layer 26 are sequentially formed on a substrate 20. A p-electrode layer 27 is formed on the p-upper cladding layer 26. The p-upper cladding layer 26 can have a mesa structure, and optionally, an electron blocking layer 25 can further be formed in the p-optical waveguide layer 24. Also, the n-lower cladding layer 21 can further include an n-electrode (not shown) for applying current.

In the present embodiment, the thickness of the n-optical waveguide layer 22 is greater than that of the p-optical waveguide layer 24. More particularly, the thickness of the n-optical waveguide layer 22 may be in a range of 50 to 1000 nm. The p-optical waveguide layer has a thickness range of 10-500 nm and its thickness is generally less than 50% of the thickness of the n-optical layer, in various exemplary embodiments. This difference in thicknesses improves the optical extraction efficiency by causing the optical mode to be disposed closer to a p-doped layer (the p-optical waveguide layer 24 and the p-upper cladding layer 26) than to an n-doped layer (the n-optical waveguide layer 22 and the p-upper cladding layer 21) during laser oscillation and by minimizing optical degradation caused by Mg, which is used as a dopant in the p-doped layers.

Examples of materials for each layer are as follows. The substrate 20 may be formed of a semiconductor such as silicon or GaN. The n-lower cladding layer 21 and p-upper cladding layer 26 can be formed of AlₓGa₁₋ₓN (0≦x≦0.2), and particularly, the n-lower cladding layer 21 can have a single- or multi-layered structure including AlₓGa₁₋ₓN (0≦x≦0.2). The p-optical waveguide layer 24 and n-optical waveguide layer 22 can be formed of InₓGa₁₋ₓN (0≦x≦0.2). The active layer 23 can be formed of a single material or have a multi quantum wall (MQW) structure formed of, for example, Ga₁₋ₓInₓN_{y}As_{1-y}, such as GaInNAs/GaAs or GaInNAs/GaNAs. Also, the electron blocking layer 25 can be formed of AlₓGa₁₋ₓN (0≦x≦0.3).

FIG. 2B illustrates the refractive index of each layer and an optical field during laser oscillation in the semiconductor laser diode having an asymmetric optical waveguide layer shown in FIG. 2A.

Referring to FIGS. 2A and 2B, the refractive indexes of the n-optical waveguide layer 22 and the p-optical waveguide layer 24 are greater than those of the p-upper cladding layer 26 and the n-lower cladding layer 21, but smaller than that of the active layer 23. During laser oscillation, an optical field from the active layer 23 is spread through the n-optical waveguide layer 22 and the p-optical waveguide layer 24. When the thickness of the n-optical waveguide layer 22 and the p-optical waveguide layer 24 are the same, the optical field may spread symmetrically around the active layer 23. However, since the disclosed exemplary embodiment has the asymmetric structure in which the thickness of the n-optical waveguide layer 22 is greater than that of the p-optical waveguide layer 24, the optical field will be spread asymmetrically, biased toward the n-optical waveguide layer 22, as shown on FIG. 2B.

To determine the characteristics of the semiconductor laser diode having an asymmetric optical waveguide layer according to an embodiment of the present disclosure, optical extraction was measured using laser diodes in which the thickness of p-optical waveguide layer 24 was fixed to 30 nm, the amount of Al in the n-lower cladding layer 21 was varied to 4% and 6%, and the thickness of the n-optical waveguide layer 22 was varied.

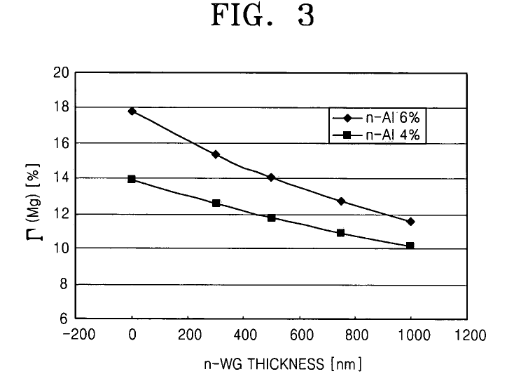

FIG. 3 is a graph of the confinement factor of a Mg doped layer (Γ(Mg)) versus the thickness of the n-optical waveguide layer 22. The n-optical waveguide layer 22 was formed of GaN (x=0). The confinement factor of the Mg doped domain (including p-optical waveguide layer and p-upper cladding layer), the Mg being the p-type dopant represents the proportion of the optical field in the Mg doped domain.

Referring to FIG. 3, as the thickness of the n-optical waveguide layer 22 increases, Γ(Mg) decreases. In detail, when the thickness of the n-optical waveguide layer 22 is 100 nm, Γ(Mg) is about 30% lower than when the thickness of the n-optical waveguide layer 22 is the same as the thickness of p-optical waveguide layer 24, which is 30 nm. Hence as the thickness of the n-optical waveguide layer 22 increases, Γ(Mg) decreases, which results in a decrease of optical loss.

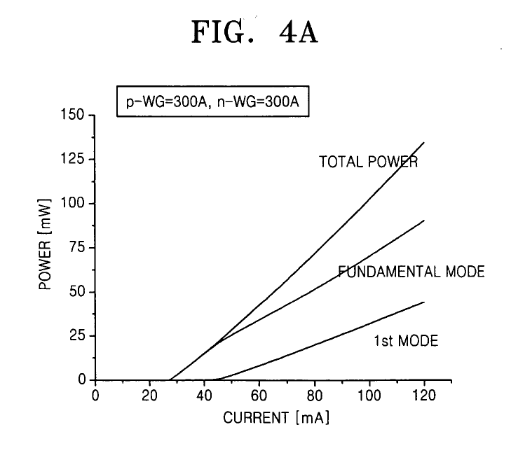

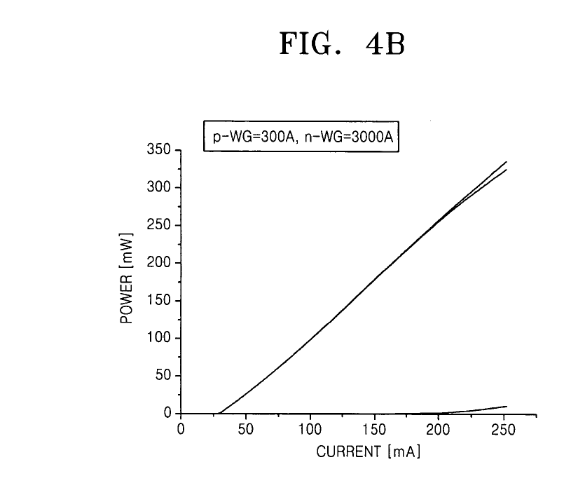

FIGS. 4A and 4B are graphs of the intensity of optical oscillation according to the current applied to a laser diode. FIG. 4A is a graph of optical output intensity against current applied to a laser diode when the thicknesses of a p-optical waveguide layer and an n-optical waveguide layer are both about 30 nm. FIG. 4B is a graph of optical output intensity against current applied to a laser diode when the thicknesses of a p-optical waveguide layer and an n-optical waveguide layer are about 30 nm and 300 nm, respectively.

Referring to FIG. 4A, when the thickness of the p-optical waveguide layer 24 and that of the n-optical waveguide layer 22 are identical at 30 nm, i.e. in the case of a semiconductor laser diode according to the prior art, the first mode light oscillates at 45 mA and the semiconductor laser diode operates in a multi-transverse mode.

However referring to FIG. 4B, a semiconductor laser diode having an asymmetric optical waveguide structure according to an embodiment of the present disclosure, in which the thicknesses of the p-optical waveguide layer 24 and the n-optical waveguide layer 22 are about 30 nm and 300 nm, respectively, has a first mode with a much greater threshold than the first mode in the prior art, and operates in a single transverse mode until about 250 mW.

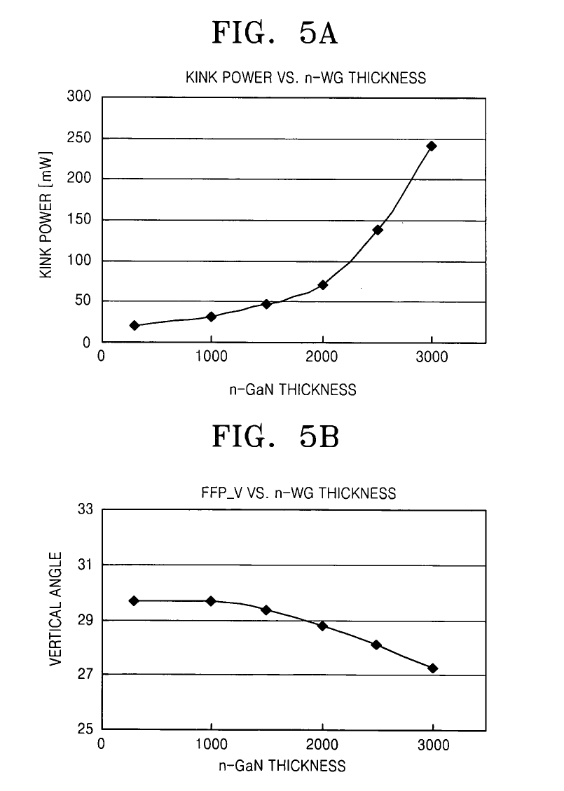

FIG. 5A is a graph of kink power against the thickness of the n-optical waveguide layer 22 between 30 and 300 nm when that the thickness of the p-optical waveguide layer 24 is fixed at about 30 nm.

Referring to FIG. 5A, when the thickness of the p-optical waveguide layer 24 and that of the n-optical waveguide layer 22 are identical at 30 nm, the kink energy (the energy at which the total power and a fundamental mode are divided) is about 25 mW as shown on FIG. 4A. However, as the thickness of the n-optical waveguide layer 22 increased, the kink energy increased as well up to 250 mW, as shown on FIG. 4B. Hence, as the thickness of the n-optical waveguide layer 22 increases, the n-optical waveguide layer 22 blocks the light at higher-order modes during laser diode oscillation, and thus produces the single transverse mode.

FIG. 5B is a graph of a vertical angle of a far field pattern with respect to the thickness of the n-optical waveguide layer 22 when the thickness of the p-optical waveguide layer 24 is fixed at about 30 nm.

Referring to FIG. 5B, when the thicknesses of both the p-optical waveguide layer 24 and the n-optical waveguide layer 22 are 30 nm, the vertical angle of far field pattern is almost about 30° However, as the thickness of the n-optical waveguide layer 22 increases, the vertical angel of the far field pattern decreases.

Various embodiments of the present disclosure have the following advantages.

First, by forming the n-optical waveguide layer with a greater thickness than the p-optical waveguide layer, the two waveguide layers being formed on and below an active layer, optical loss due to a crystalline defect caused by impurities in the upper cladding layer can be prevented. Thus, a threshold current can be lowered and a reduction in optical extraction efficiency caused by a high applied current can be prevented.

Second, a gain different between a fundamental mode and a 1^{st} order mode can be enlarged, which can enhance the kink energy of the laser diode device by restraining a higher order mode.

Third, by forming the n-optical waveguide layer sufficiently thick, the size of a near field which is confined to the n-optical waveguide layer can be increased. Therefore the centralization of light in a p-doped layer decreased, which can prevent catastrophic optical damage (COD) and decrease a far field vertical angle.

Fourth, when the thickness of an n-type cladding layer is great, it can cause cracks and have bad effects on a semiconductor device. Therefore, the thickness of the n-optical waveguide layer in which cracks are less likely to occur is adjusted to prevent cracks. Of course, not all embodiments of the invention as set forth in the claims appended hereto necessarily will have every one, or even any, of the foregoing advantages depending on various factors.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor laser diode having an asymmetric optical waveguide layer, comprising an n-lower cladding layer, an n-optical waveguide layer, an active layer, a p-optical waveguide layer and a p-upper cladding layer which are sequentially formed on a substrate, wherein the thickness of the n-optical waveguide layer is greater than the thickness of the p-optical waveguide layer.

2. The semiconductor laser diode of claim 1, wherein the thickness of the n-optical waveguide layer is in a range of 50 to 1000 nm.

3. The semiconductor laser diode of claim 1, wherein the p-optical waveguide layer has a single- or multi-layered structure and includes InₓGa₁₋ₓN where 0≦x≦0.2.

4. The semiconductor laser diode of claim 1, further comprising a p-electrode formed on the p-upper cladding layer, wherein the p-upper cladding layer has a mesa structure with a central portion that protrudes.

5. The semiconductor laser diode of claim 1, further comprising an electron blocking layer formed in the p-optical waveguide layer.

6. The semiconductor laser diode of claim 1, wherein the active layer has a multiple quantum well (MQW) structure.

7. The semiconductor laser diode of claim 1, wherein the p-optical waveguide layer is doped with Mg.
